(19) United States
(12) Patent Application Publication
(10) Pub. No.: US 2008/0157889 A1
(43) Pub. Date: Jul. 3, 2008

(54) Voltage Controlled Oscillator for Maintaining Stable Oscillation Frequency Against Fluctuation of Power Supply Voltage

(76) Inventor: Jin Hyuck Yu, Hwaseong-si (KR)

Correspondence Address: F. CHAU & ASSOCIATES, LLC, 130 WOODBURY ROAD, WOODBURY, NY, 11797, US

(21) Appl. No.: 11/764,649

(22) Filed: Jun. 18, 2007

(30) Foreign Application Priority Data
Dec. 28, 2006 (KR) 10-2006-0136237

(51) Int. Cl. H03B 7/06; H03L 7/00

(52) U.S. Cl. 331/1 R; 331/115

(57) ABSTRACT

A voltage controlled oscillator includes an L-C tank circuit configured to have a first capacitance that increases as a power supply voltage increases, and a capacitance compensation circuit configured to be connected in parallel with both terminals of the L-C tank circuit and to have a second capacitance that decreases as the power supply voltage increases. The voltage controlled oscillator maintains the sum of the first capacitance and the second capacitance constant regardless of the fluctuation of the power supply voltage, thereby maintaining a stable oscillation frequency.

### CROSS-REFERENCE TO RELATED PATENT APPLICATION

This application claims the benefit of Korean Patent Application No. 10-2006-0136237, filed on Dec. 28, 2006, in the Korean Intellectual Property Office, the disclosure of which is incorporated herein in its entirety by reference.

### FIELD OF THE INVENTION

The present disclosure relates to a voltage controlled oscillator (VCO) and, more particularly, to a VCO for preventing a change of the oscillation frequency that occurs based on a change of capacitance of the VCO occurring due to a fluctuation of the power supply voltage.

### BACKGROUND OF THE INVENTION

A voltage controlled oscillator (VCO) is a device that outputs a signal having a variable frequency based on the fluctuation of a tuning voltage and is used to maintain a stable frequency or to accurately vary the frequency. Electronic apparatuses (for example, mobile devices, computers, and broadcasting equipment) that include a synchronization circuit usually include a phase locked loop (PLL) or a delay locked loop (DLL). The PLL or the DLL maintains a stable frequency and accurately varies the frequency typically using the VCO.

FIG. 1 is a block diagram of a conventional PLL 1. The PLL 1 includes a phase frequency detector (PFD) 10, a charge pump (CP) 20, a loop filter 30, and a VCO 40.

The phase frequency detector 10 compares the phase of a reference signal fref with the phase of an output signal fvco and generates phase control signals UP and DOWN that correspond to a difference between the phases of the two inputs. The CP 20 generates a charge corresponding to the phase control signals UP and DOWN. The loop filter 30 may be a low pass filter (LPF). The loop filter 30 generates a tuning voltage Vtune based on a signal output from the CP 20. The VCO 40 is supplied with a power supply voltage VCC by a regulator (not shown) and generates the output signal fvco having a frequency proportional to the tuning voltage Vtune.

FIG. 2 illustrates the structure of a regulator 50 for stabilizing the power supply voltage VCC of the VCO 40 illustrated in FIG. 1. The regulator 50 includes a reference voltage generator 52, a LPF 54, and an operational amplifier 56.

The VCO 40 receives the power supply voltage VCC that has been stabilized using the regulator 50 that includes the operational amplifier 56 and, thus, has an excellent pushing characteristic. The pushing characteristic is expressed as a ratio of the change of an oscillation frequency of the VCO 40 to the fluctuation of the power supply voltage VCC in units of Hz/V. The regulator 50 includes the reference voltage generator 52 and the operational amplifier 56, however, thereby increasing the layout area of the VCO 40. In addition, the phase noise of the VCO 40 may be increased. The phase noise is expressed as a ratio of the magnitude of noise to the magnitude of a signal having a predetermined oscillation frequency in units of dB.

### SUMMARY OF THE INVENTION

Exemplary embodiments of the present invention provide a voltage controlled oscillator (VCO) for enhancing a pushing characteristic in a small layout area.

According to exemplary embodiments of the present invention, there is provided a VCO including an L-C tank circuit and a capacitance compensation circuit. The L-C tank circuit has a first capacitance that increases as a power supply voltage increases. The capacitance compensation circuit is connected in parallel with both terminals of the L-C tank circuit and has a second capacitance that decreases as the power supply voltage increases.

The VCO may maintain the sum of the first capacitance and the second capacitance constant regardless of the increase of the power supply voltage, thereby maintaining a stable oscillation frequency against the fluctuation of the power supply voltage.

The capacitance compensation circuit may include a plurality of capacitors and a plurality of varactors, which are connected in series between both terminals of the L-C tank circuit, and a first power supply circuit configured to be connected between a first voltage line supplying the power supply voltage and a second voltage line and to supply power to a common node of the plurality of varactors in response to a control signal.

Alternatively, the capacitance compensation circuit may include a first capacitor and a first varactor, which are connected in series between one of the terminals of the L-C tank circuit and the common node; a second capacitor and a second varactor, which are connected in series between the other terminal of the L-C tank circuit and the common node; and a first power supply circuit configured to supply the power supply voltage to the common node in response to a control signal.

The capacitance compensation circuit may further include a second power supply circuit configured to supply a predetermined voltage to a common node of the first capacitor and the first varactor and a common node of the second capacitor and the second varactor.

### BRIEF DESCRIPTION OF THE DRAWINGS

Exemplary embodiments of the present invention will be understood in more detail from the following descriptions taken in conjunction with the attached drawings in which:

FIG. 1 is a block diagram of a conventional phase locked loop (PLL);

FIG. 2 illustrates the structure of a regulator for supplying a power supply voltage to a voltage controlled oscillator (VCO) illustrated in FIG. 1;

FIG. 3A is a graph schematically illustrating the capacitance of a conventional VCO versus a power supply voltage;

FIG. 3B is a graph schematically illustrating the capacitance of a capacitance compensation circuit versus a power supply voltage, according to an exemplary embodiment of the present invention;

FIG. 3C is a graph schematically illustrating the capacitance of a VCO including a capacitance compensation circuit versus a power supply voltage, according to an exemplary embodiment of the present invention;

FIG. 4 illustrates the structure of a VCO according to an exemplary embodiment of the present invention;

FIG. 5 is a circuit diagram of a capacitance compensation circuit according to an exemplary embodiment of the present invention;

FIG. 6 is a graph illustrating the capacitance between both ends of each varactor illustrated in FIG. 5 versus a source-gate voltage;

FIG. 7 is a graph illustrating the result of a simulation of comparing the pushing characteristic of a conventional VCO with that of a VCO according to an exemplary embodiment of the present invention; and

FIG. 8 is a block diagram of an electronic device that processes data in response to an output signal of a VCO according to an exemplary of the present invention.

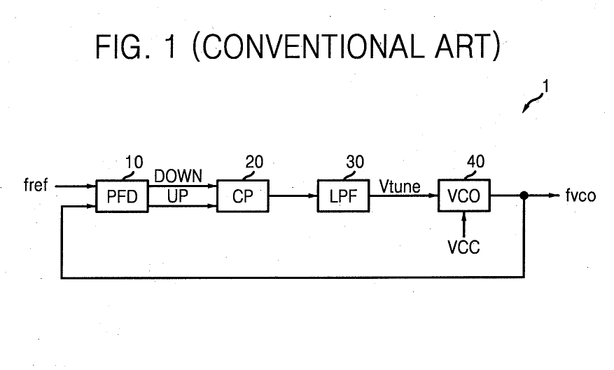

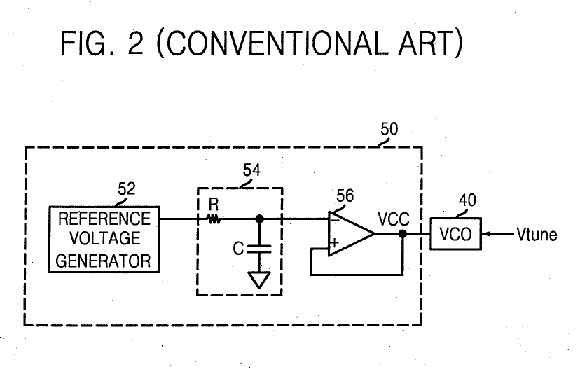

### DETAILED DESCRIPTION OF EXEMPLARY EMBODIMENTS

Exemplary embodiments of the present invention now will be described more fully hereinafter with reference to the accompanying drawings, in which the exemplary embodiments of the invention are shown. This invention may however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the drawings, like numbers refer to like elements throughout.

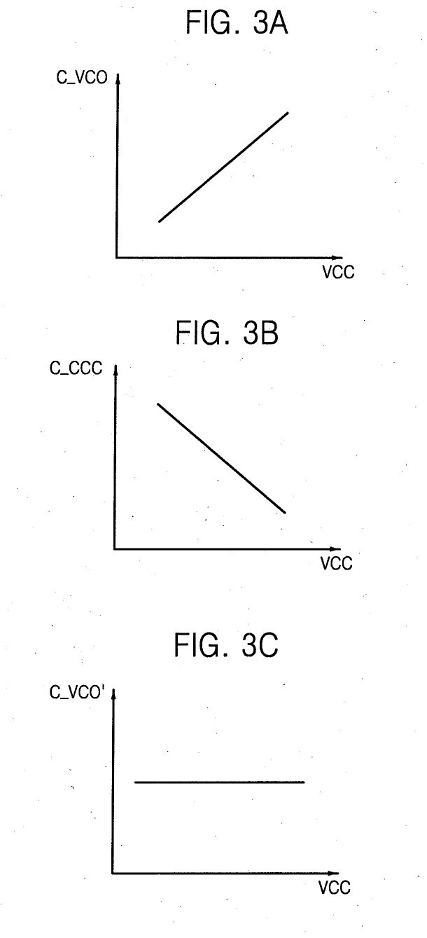

FIG. 3A is a graph schematically illustrating a capacitance C_VCO of a conventional voltage controlled oscillator (VCO) versus a power supply voltage VCC. Referring to FIG. 3A, it is seen that the capacitance C_VCO of the conventional VCO increases as the power supply voltage VCC increases.

FIG. 3B is a graph schematically illustrating a capacitance C_CCC of a capacitance compensation circuit (CCC) versus the power supply voltage VCC, according to an exemplary embodiment of the present invention. Referring to FIG. 3B, it is seen that the capacitance C_CCC of the CCC decreases as the power supply voltage VCC increases.

FIG. 3C is a graph schematically illustrating a capacitance C_VCO′ of a VCO including the CCC versus the power supply voltage VCC, according to an exemplary embodiment of the present invention. Referring to FIG. 3C, it is seen that the capacitance C_VCO′ of the VCO is maintained constant regardless of the value of the power supply voltage VCC. This constant capacitance C_VCO′ is obtained by the CCC performing compensation of the effective capacitance of the conventional VCO, which increases as the power supply voltage VCC increases. The CCC enhances the pushing characteristic of the VCO. In other words, according to exemplary embodiments of the present invention, the VCO can maintain a stable oscillation frequency despite changes in the level of the power supply voltage VCC.

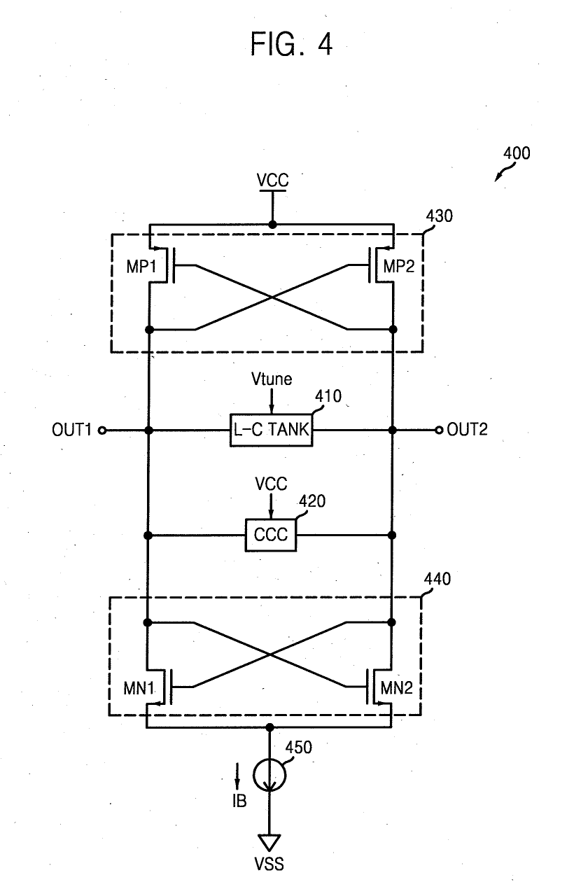

FIG. 4 illustrates the structure of a VCO 400 according to an exemplary embodiment of the present invention. The VCO 400 includes an L-C tank circuit 410, a CCC 420, a negative conductance generation circuit including blocks 430 and 440, and a bias circuit 450.

The L-C tank circuit 410 outputs an output signal having a predetermined oscillation frequency through first and second output terminals OUT1 and OUT2 in response to a tuning voltage Vtune. Referring to FIG. 3A, the L-C tank circuit 410 has a first capacitance that increases as the power supply voltage VCC increases. Because the first capacitance may vary based on the power supply voltage VCC, the oscillation frequency of the output signal may be shifted, which results in the deterioration of the pushing characteristic of the VCO 400.

The CCC 420 is connected in parallel with both ends of the L-C tank circuit 410 and has a second capacitance that decreases as the power supply voltage VCC increases. Thus, the sum of the first capacitance and the second capacitance is maintained constant regardless of the increase of the power supply voltage VCC. In other words, the CCC 420 compensates for the capacitance change of the L-C tank circuit 410, which occurs based on changes of the power supply voltage VCC, thereby enhancing the pushing characteristic of the VCO 400.

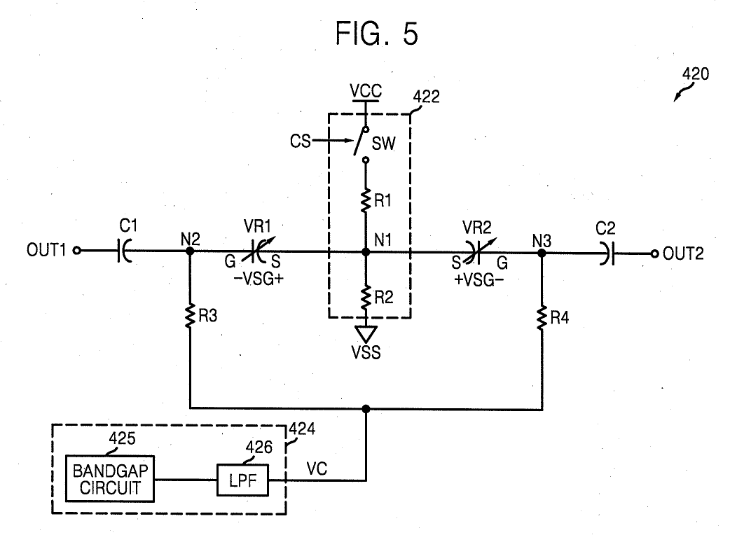

FIG. 5 is a circuit diagram of the CCC 420 according to an exemplary embodiment of the present invention. Referring to FIG. 5, the CCC 420 includes a first power supply circuit 422, a plurality of capacitors C1 and C2, a plurality of varactors VR1 and VR2, and a second power supply circuit 424.

The first power supply circuit 422 is connected between a first voltage line supplying the power supply voltage VCC and a second voltage line supplying a ground voltage VSS and supplies power to a common node (hereinafter, referred to as a “first node”) N1 of the plurality of the varactors VR1 and VR2. The first power supply circuit 422 includes a first resistor R1, which is connected between the first voltage line VCC and the first node N1 via a switch SW, and a second resistor R2, which is connected between the first node N1 and the second voltage line VSS. The switch SW selectively supplies the power supply voltage VCC to the CCC 420 in response to a control signal CS. The voltage of the first node N1 is obtained from the power supply voltage VCC divided by the first resistor R1 and the second resistor R2 and thus reflects any changes of the power supply voltage VCC.

The plurality of capacitors C1 and C2 and the plurality of varactors VR1 and VR2 are connected in series between both ends OUT1 and OUT2 of the L-C tank circuit 410. The first capacitor C1 and the first varactor VR1 are connected in series between one end, for example, the first output terminal OUT1, of the L-C tank circuit 410 and the first node N1. The second capacitor C2 and the second varactor VR2 are connected in series between the other end, for example, the second output terminal OUT2, of the L-C tank circuit 410 and the first node N1.

The first and second varactors VR1 and VR2 have the second capacitance that decreases as the power supply voltage VCC increases, thereby counterbalancing the first capacitance of the L-C tank circuit 410, which increases as the power supply voltage VCC increases. In other words, the first and second varactors VR1 and VR2 maintain the sum of the first capacitance and the second capacitance constant in the face of changes of the power supply voltage VCC, thereby preventing a change of the oscillation frequency of the output signal of the VCO 400. As a result, the pushing characteristic of the VCO 400 is enhanced.

The first and second varactors VR1 and VR2 may be accumulation metal oxide semiconductor (AMOS) varactors. Referring to FIG. 5, a source S of the first varactor VR1 is connected with the first node N1 and a gate of the first varactor VR1 is connected with a common node (hereinafter, referred to as a “second node”) N2 of the first capacitor C1 and the first varactor VR1. A source S of the second varactor VR2 is connected with the first node N1 and a gate of the second varactor VR2 is connected with a common node (hereinafter, referred to as a “third node”) N3 of the second capacitor C2 and the second varactor VR2.

When the power supply voltage VCC increases, the voltage of the first node N1 also increases and the second and third nodes N2 and N3 receive a predetermined voltage output from the second power supply circuit 424 via a third resistor R3 and a fourth resistor R4, respectively. Accordingly, when the power supply voltage VCC increases, a respective source-gate voltage VSG of the first and second varactors VR1 and VR2 also increases. When the power supply voltage VCC decreases, the respective source-gate voltage VSG of the first and second varactors VR1 and VR2 also decreases.

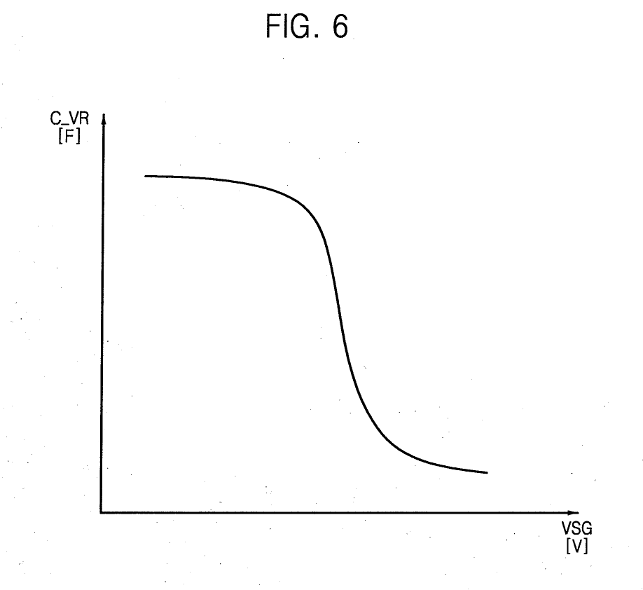

FIG. 6 is a graph illustrating a capacitance C_VR between both ends of the varactors VR1 and VR2 illustrated in FIG. 5 versus the source-gate voltage VSG. Referring to FIG. 6, the capacitance C_VR decreases as the respective source-gate voltage VSG of the first and second varactors VR1 and VR2 increases. As a result, the first and second varactors VR1 and VR2 counterbalance the change of the first capacitance of the L-C tank circuit 410, which occurs based on changes of the power supply voltage VCC.

The first and second capacitors C1 and C2 block noise from being input to the first and second varactors VR1 and VR2, respectively. The first capacitor C1 is connected between the second node N2 and the first output terminal OUT1. The second capacitor C2 is connected between the third node N3 and the second output terminal OUT2. The first and second capacitors C1 and C2 may be metal insulator metal (MIM) capacitors.

The second power supply circuit 424 supplies a predetermined voltage VC to the resistors R3 and R4 connected respectively to the second node N2 and the third node N3. The second power supply circuit 424 includes a voltage generator 425, which generates the predetermined voltage VC, and a low pass filter (LPF) 426, which outputs the predetermined voltage VC after removing noise from the predetermined voltage VC output from the voltage generator 425. As illustrated in FIG. 5, the voltage generator 425 may be implemented by a bandgap circuit.

Referring to FIG. 4, the negative conductance generation circuit 430 and 440 provides a negative resistance so that the VCO 400 can oscillate stably. The negative conductance generation circuits 430 and 440 respectively include a pair of first conductivity type transistors MP1 and MP2, which are cross coupled, and a pair of second conductivity type transistors MN1 and MN2, which are cross coupled. The first conductivity type transistors MP1 and MP2 may be one channel type between an N channel type and a P channel type while the second conductivity type transistors MN1 and MN2 may be the other channel type between the N channel type and the P channel type.

The bias circuit 450 provides a bias current 1B for the VCO 400.

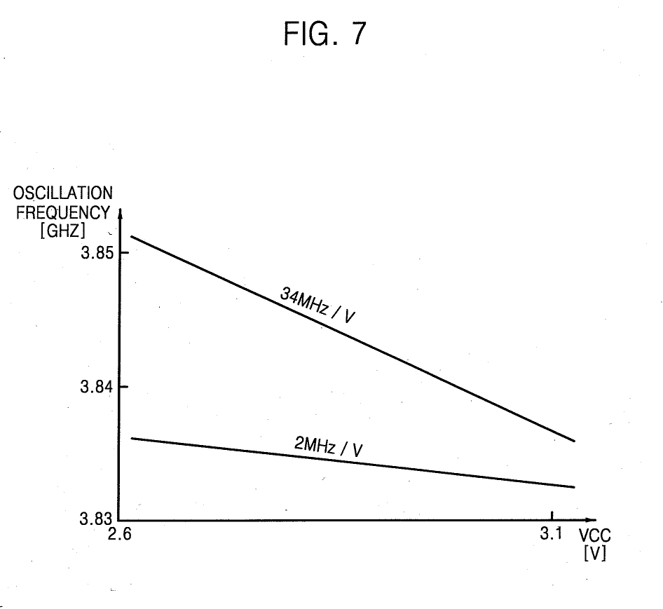

FIG. 7 is a graph illustrating the result of a simulation of comparing the pushing characteristic of a conventional VCO with that of the VCO 400 including the CCC 420 according to an exemplary embodiment of the present invention. Referring to FIG. 7, while the conventional VCO has a pushing characteristic of 34 MHz/V, the VCO 400 including the CCC 420 according to an exemplary embodiment of the present invention has a pushing characteristic of 2 MHz/V. This means that the VCO 400 including the CCC 420 according to exemplary embodiments of the present invention can maintain an oscillation frequency more stably than the conventional VCO with respect to changes in the power supply voltage VCC.

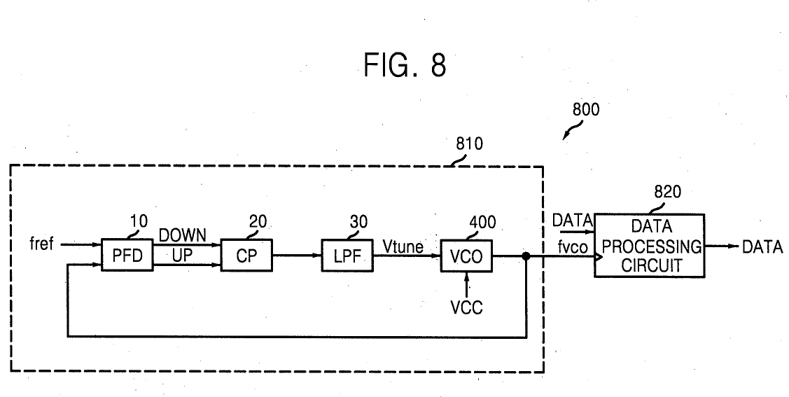

FIG. 8 is a block diagram of an electronic device 800 that processes data DATA fed thereto in response to an output signal fvco of the VCO 400, according to an exemplary embodiment of the present invention. The electronic device 800 includes a phase locked loop (PLL) 810 including the VCO 400 according to an exemplary embodiment of the present invention and a data processing circuit 820.

The data processing circuit 820 processes the data DATA in response to the output signal fvco of the PLL 810. The electronic device 800 may be any electronic device such as a mobile device, a computer, broadcasting equipment, or a memory card, which processes data DATA in synchronization with the output signal fvco of the PLL 810.

As described above, a VCO according to exemplary embodiments of the present invention compensates for the capacitance of an L-C tank circuit that varies with changes of a power supply voltage so as to maintain the total capacitance of the VCO constant. As a result, an oscillation frequency is prevented from changing due to changes of the power supply voltage.

While the present invention has been shown and described with reference to exemplary embodiments thereof, it will be understood by those of ordinary skill in the art that various changes in form and detail may be made herein without departing from the spirit and scope of the present invention, as defined by the following claims.

What is claimed is:

1. A voltage controlled oscillator comprising:
an L-C tank circuit configured to have a first capacitance that increases as a power supply voltage increases; and
a capacitance compensation circuit connected in parallel with both terminals of the L-C tank circuit and configured to have a second capacitance that decreases as the power supply voltage increases.

2. The voltage controlled oscillator of claim 1, wherein a sum of the first capacitance and the second capacitance is constant regardless of the increase of the power supply voltage.

3. The voltage controlled oscillator of claim 1, wherein the capacitance compensation circuit comprises:
a plurality of capacitors and a plurality of varactors connected in series between both terminals of the L-C tank circuit; and
a first power supply circuit connected between a first voltage line supplying the power supply voltage and a second voltage line and configured to supply power to a common node of the plurality of varactors in response to a control signal.

4. The voltage controlled oscillator of claim 1, wherein the capacitance compensation circuit comprises:
a node;
a first capacitor and a first varactor, which are connected in series between one of the terminals of the L-C tank circuit and the node;
a second capacitor and a second varactor connected in series between the other of the terminals of the L-C tank circuit and the node; and
a first power supply circuit configured to supply the power supply voltage to the node in response to a control signal.

5. The voltage controlled oscillator of claim 4, wherein the capacitance compensation circuit further comprises a second power supply circuit configured to supply a predetermined voltage to a common node of the first capacitor and the first varactor and to a common node of the second capacitor and the second varactor.

6. The voltage controlled oscillator of claim 1, wherein an input and an output thereof are included in a phase locked loop.

7. The voltage controlled oscillator of claim 4, wherein the first and second varactors are accumulation metal oxide semiconductor (AMOS) varactors.

8. The voltage controlled oscillator of claim 4, wherein the first and second capacitors are metal insulator metal (MIM) capacitors.

9. The voltage controlled oscillator of claim 5, wherein the first and second varactors are accumulation metal oxide semiconductor (AMOS) varactors.

10. The voltage controlled oscillator of claim 5, wherein the first and second capacitors are metal insulator metal (MIM) capacitors.

11. The voltage controlled oscillator of claim 1, further comprising a negative conductance circuit configured to provide a negative resistance for the voltage controlled oscillator so that the voltage controlled oscillator maintains a stable oscillation.

12. An electronic device comprising:
a voltage controlled oscillator including
an L-C tank circuit configured to have a first capacitance that increases as a power supply voltage increases;
a capacitance compensation circuit connected in parallel with both terminals of the L-C tank circuit and configured to have a second capacitance that decreases as the power supply voltage increases to generate a clock signal having a predetermined oscillation frequency; and
a data processing circuit configured to process data in response to the clock signal.

13. A method of operating a voltage controlled oscillator including an L-C tank circuit and a capacitance compensation circuit, the method comprising:
changing a first capacitance of the L-C tank circuit based on a power supply voltage; and
changing a second capacitance of the capacitance compensation circuit in response to the power supply voltage so that a sum of the first capacitance and the second capacitance is maintained constant regardless of changes in the power supply voltage.

14. The method of claim 13, wherein the step of changing the second capacitance comprises:
supplying the power supply voltage to a node of the capacitance compensation circuit in response to a control signal; and
supplying a predetermined voltage to a common node of a first capacitor and a first varactor of the capacitance compensation circuit and to a common node of a second capacitor and a second varactor of the capacitance compensation circuit.

15. The method of claim 14, further comprising removing noise input to each of the first and second varactors.
